(19) United States
(12) Patent Application Publication
(10) Pub. No.: US 2026/0157132 A1
(43) Pub. Date: Jun. 4, 2026

(54) PLASMA PROCESSING APPARATUS AND SEMICONDUCTOR DEVICE MANUFACTURING METHOD

(71) Applicant: Kioxia Corporation, Tokyo (JP)

(72) Inventor: Nobuhiko HORI, Yokkaichi Mie (JP)

(73) Assignee: Kioxia Corporation, Tokyo (JP)

(21) Appl. No.: 19/458,276

(22) Filed: Jan. 23, 2026

Related U.S. Application Data
(62) Division of application No. 17/691,856, filed on Mar. 10, 2022.

(30) Foreign Application Priority Data
Aug. 25, 2021 (JP) 2021-137016

(51) Int. Cl. H10P 50/28; H01J 37/32; H10P 50/00

(52) U.S. Cl. CPC H10P 50/283; H01J 37/32082; H01J 37/32568; H01J 37/32715; H10P 50/73; H01J 2237/327; H01J 2237/332

(57) ABSTRACT

A plasma processing apparatus of an embodiment includes: a processing container in which a substrate is processed; an upper electrode that is installed in the processing container; a substrate placement table that includes a lower electrode facing the upper electrode and on which the substrate is placed; an outer circumferential ring that is arranged on an outer edge portion of the substrate placement table and surrounds a periphery of the substrate; and a power supply that supplies power to at least one of the upper electrode and the lower electrode to generate plasma in the processing container, in which the outer circumferential ring has a pattern including a component of a deposition film generated by a plasma reaction on an outermost surface.

### CROSS-REFERENCE TO RELATED APPLICATIONS

This application is a divisional of U.S. application Ser. No. 17/691, 856, filed Mar. 10, 2022, which is based upon and claims the benefit of priority from Japanese Patent Application No. 2021-137016, filed on Aug. 25, 2021; the entire contents of which are incorporated herein by reference.

### FIELD

Embodiments described herein relate generally to a plasma processing apparatus and a semiconductor device manufacturing method.

### BACKGROUND

In a process of manufacturing a semiconductor device, plasma processing may be performed on a substrate. At this time, the concentration and the like of a predetermined product by the plasma reaction may be different between a central portion and an outer edge portion of the substrate. In this case, the processing characteristics may be different between the central portion and the outer edge portion of the substrate.

### BRIEF DESCRIPTION OF THE DRAWINGS

FIG. 1 is a perspective top view schematically illustrating an example of an overall configuration of a plasma processing apparatus according to an embodiment;

FIG. 2 is a cross-sectional view schematically illustrating an example of a configuration of a processing chamber included in the plasma processing apparatus according to the embodiment;

FIGS. 3A and 3B are diagrams illustrating an example of a detailed configuration of an outer circumferential ring according to the embodiment;

FIGS. 4A to 4F are cross-sectional views illustrating an example of a procedure of imprint processing and plasma processing on a wafer according to the embodiment;

FIGS. 5A to 5F are top views illustrating an example of a detailed procedure of the imprint processing on a wafer according to the embodiment;

FIGS. 6A to 6F are top views illustrating an example of a procedure of processing of forming a pattern on an upper surface of an upper ring according to the embodiment;

FIG. 7 is a flowchart illustrating an example of a use cycle of the outer circumferential ring according to the embodiment;

FIG. 8 is a flowchart illustrating an example of a procedure of plasma processing using the outer circumferential ring according to the embodiment;

FIG. 9 is a top view illustrating an example of a configuration of an outer circumferential ring included in a plasma processing apparatus according to a first modification of the embodiment; and

FIG. 10 is a top view illustrating an example of a configuration of an outer circumferential ring included in a plasma processing apparatus according to a second modification of the embodiment.

### DETAILED DESCRIPTION

A plasma processing apparatus of an embodiment includes: a processing container in which a substrate is processed; an upper electrode that is installed in the processing container; a substrate placement table that includes a lower electrode facing the upper electrode and on which the substrate is placed; an outer circumferential ring that is arranged on an outer edge portion of the substrate placement table and surrounds a periphery of the substrate; and a power supply that supplies power to at least one of the upper electrode and the lower electrode to generate plasma in the processing container, in which the outer circumferential ring has a pattern including a component of a deposition film generated by a plasma reaction on an outermost surface.

Hereinafter, the present invention will be described in detail with reference to the drawings. Note that the present invention is not limited by the embodiment described below. In addition, constituent elements in the embodiment described below include those that can be easily assumed by those skilled in the art or those that are substantially the same.

### Configuration Example of the Plasma Processing Apparatus

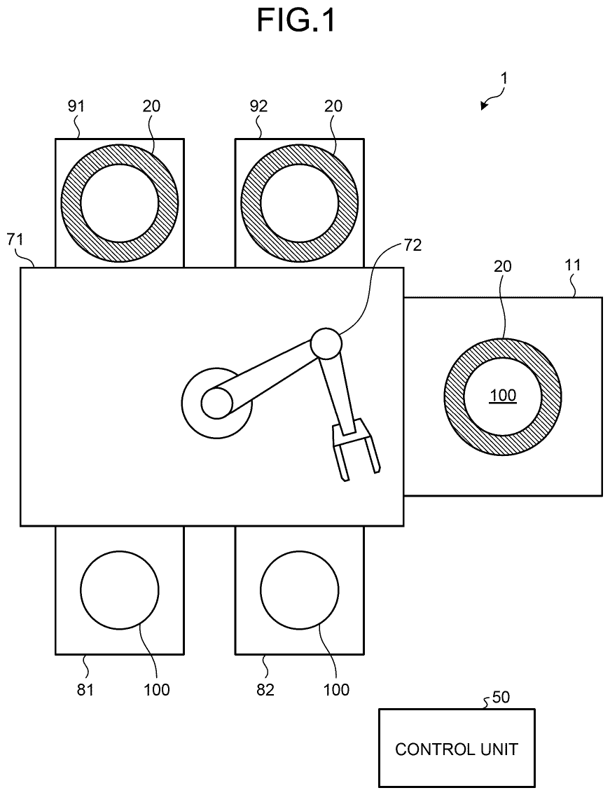

FIG. 1 is a perspective top view schematically illustrating an example of an overall configuration of a plasma processing apparatus 1 according to the embodiment. As illustrated in FIG. 1, the plasma processing apparatus 1 includes a processing chamber 11, a transfer chamber 71, load locks 81, 82, 91, and 92, and a control unit 50.

The processing chamber 11, which is a processing container, is a container for performing plasma processing on a wafer 100, and is connected to the transfer chamber 71 in an airtightly sealed state. The wafer 100 accommodated in the processing chamber 11 is processed by plasma in a state where an outer circumferential ring 20 is arranged on the outer circumference.

The load lock 81 is a container for storing the wafer 100 to be processed, and is connected to the transfer chamber 71 in an airtightly sealed state. The load lock 81 is configured to be capable of accommodating a plurality of wafers 100, for example, wafers 100 for one lot.

The load lock 82 is a container for collecting the processed wafer 100, and is connected to the transfer chamber 71 in an airtightly sealed state. The load lock 82 is configured to be capable of accommodating a plurality of wafers 100, for example, wafers 100 for one lot.

The load lock 91, which is a storage container, is a container for storing the outer circumferential ring 20 arranged on the outer circumference of the wafer 100 at the time of plasma processing, and is connected to the transfer chamber 71 in an airtightly sealed state. The load lock 91 is configured to be capable of accommodating, for example, the same number of outer circumferential rings 20 as the wafers 100 stored in the load lock 81.

The load lock 92, which is a collection container, is a container for collecting the outer circumferential ring 20 used for the plasma processing, and is connected to the transfer chamber 71 in an airtightly sealed state. The load lock 92 is configured to be capable of accommodating, for example, the same number of outer circumferential rings 20 as the wafers 100 stored in the load lock 81, that is, the same number as the outer circumferential rings 20 stored in the load lock 91.

Note that, as described below, the outer circumferential ring 20 includes several parts. Therefore, the plasma processing apparatus 1 may include a plurality of sets of load locks 91 and 92 for each individual part of the outer circumferential ring 20.

The transfer chamber 71 is a container for transferring the wafer 100 and the outer circumferential ring 20 under reduced pressure, and is configured to be capable of being airtightly sealed. The transfer chamber 71 includes a transfer arm 72 that transfers the wafer 100 and the outer circumferential ring 20.

The transfer arm 72 transfers the wafer 100 from the load lock 81 to the processing chamber 11, and transfers the wafer 100 from the processing chamber 11 to the load lock 82. In addition, the transfer arm 72 transfers the outer circumferential ring 20 from the load lock 91 to the processing chamber 11, and transfers the outer circumferential ring 20 from the processing chamber 11 to the load lock 92. However, the plasma processing apparatus 1 may include a transfer arm that transfers the wafer 100 and a transfer arm that transfers the outer circumferential ring 20.

The control unit 50 controls each unit of the plasma processing apparatus 1 including the transfer arm 72. The control unit 50 is configured as a computer including a central processing unit (CPU), a read only memory (ROM), a random access memory (RAM), and the like, which are not illustrated.

However, the control unit 50 may be configured as an application specific integrated circuit (ASIC) or the like having a function for use in the plasma processing apparatus 1.

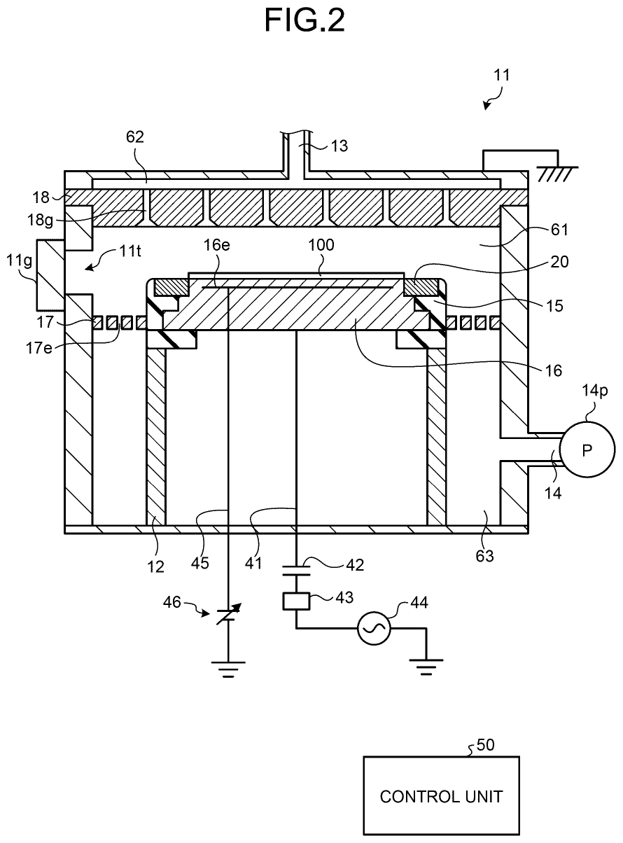

FIG. 2 is a cross-sectional view schematically illustrating an example of a configuration of the processing chamber 11 included in the plasma processing apparatus 1 according to the embodiment. The processing chamber 11 is configured to be capable of performing, for example, etching processing using plasma, and the plasma processing apparatus 1 is configured as, for example, an etching apparatus.

As illustrated in FIG. 2, the plasma processing apparatus 1 includes the processing chamber 11 for processing the wafer 100. The processing chamber 11 is made of, for example, aluminum, and can be airtightly sealed.

A loading/unloading port 11t of the wafer 100 is provided on a side surface of the processing chamber 11.

The loading/unloading port 11t airtightly seals the processing chamber 11 and includes a gate 11g that can be opened and closed when the wafer 100 is loaded and unloaded. Through the loading/unloading port 11t, the wafer 100 and the outer circumferential ring 20 are respectively placed at predetermined positions in the processing chamber 11 by the transfer arm 72 described above.

A gas supply port 13 is provided in an upper portion of the processing chamber 11. A gas supply apparatus, which is not illustrated, is connected to the gas supply port 13 through a pipe, and a processing gas used when the wafer 100 is processed is supplied.

A shower head 18 functioning as an upper electrode is provided below the gas supply port 13. The shower head 18 is provided with a plurality of gas blowing ports 18g penetrating the shower head 18 in the plate thickness direction. The processing gas supplied from the gas supply port 13 is introduced into the processing chamber 11 through the gas blowing ports 18g. An electrostatic chuck 16 is arranged below the shower head 18 so as to face the shower head 18.

The electrostatic chuck 16, which is a substrate placement table, horizontally supports the wafer 100 to be processed in the processing chamber 11, electrostatically attracts the wafer 100, and also functions as a lower electrode.

The electrostatic chuck 16 is supported on a support portion 12 protruding in a cylindrical shape vertically upward from a bottom wall in the vicinity of the center of the processing chamber 11. The support portion 12 supports the electrostatic chuck 16 in the vicinity of the center of the processing chamber 11 at a predetermined distance from the shower head 18 so as to face the shower head 18 in parallel. With such a structure, the shower head 18 and the electrostatic chuck 16 constitute a pair of parallel plate electrodes.

In addition, the electrostatic chuck 16 includes a chuck mechanism that electrostatically attracts the wafer 100. The chuck mechanism includes a chuck electrode 16e, a power supply line 45, and a power supply 46. The power supply 46 is connected to the chuck electrode 16e via the power supply line 45. With such a mechanism, direct-current power is supplied from the power supply 46 to the chuck electrode 16e, the upper surface of the electrostatic chuck 16 is electrostatically charged, and the wafer 100 is attracted.

In addition, a power supply line 41 is connected to the electrostatic chuck 16. A blocking capacitor 42, a matcher 43, and a high frequency power supply 44 are connected to the power supply line 41. At the time of plasma processing, high frequency power of a predetermined frequency is supplied from the high frequency power supply 44 to the electrostatic chuck 16. With such a mechanism, the electrostatic chuck 16 functions as a lower electrode. In addition, with such a configuration, the plasma processing apparatus 1 is configured as, for example, a lower portion application type plasma processing apparatus.

However, the plasma processing apparatus 1 may be configured as an upper portion application type plasma processing apparatus by connecting the power supply line 41 including the blocking capacitor 42, the matcher 43, the high frequency power supply 44, and the like to the shower head 18 functioning as an upper electrode.

Alternatively, the plasma processing apparatus 1 may be configured as an upper and lower portion application type plasma processing apparatus by connecting the power supply line 41 including the blocking capacitor 42, the matcher 43, the high frequency power supply 44, and the like to both the electrostatic chuck 16 and the shower head 18.

On the outer circumference of the electrostatic chuck 16, an insulator ring 15 is arranged so as to cover peripheral edge portions of the side surface and the bottom surface of the electrostatic chuck 16. The outer circumferential ring 20 is provided above the insulator ring 15 so as to surround the outer circumference of the electrostatic chuck 16.

The outer circumferential ring 20 is configured to include, for example, a silicon-based material, and adjusts the electric field so that the electric field is not deflected with respect to the vertical direction at the peripheral edge portion of the wafer 100, that is, a direction perpendicular to the surface of the wafer 100 at the time of etching the wafer 100.

A baffle plate 17 is provided between the insulator ring 15 and a sidewall of the processing chamber 11. The baffle plate 17 has a plurality of gas exhaust holes 17e penetrating the baffle plate 17 in the plate thickness direction.

A gas exhaust port 14 is provided below the baffle plate 17 of the processing chamber 11. A vacuum pump 14p that exhausts the atmosphere in the processing chamber 11 is connected to the gas exhaust port 14.

A region partitioned by the electrostatic chuck 16 and the baffle plate 17 and the shower head 18 in the processing chamber 11 is a plasma processing chamber 61. An upper region in the processing chamber 11 partitioned by the shower head 18 is a gas supply chamber 62. A lower region in the processing chamber 11 partitioned by the electrostatic chuck 16 and the baffle plate 17 is a gas exhaust chamber 63.

The control unit 50 described above controls the power supply 46, the matcher 43, the high frequency power supply 44, the gas supply apparatus, and the like.

At the time of plasma processing of the wafer 100, under the control of the control unit 50, the wafer 100 to be processed is placed on the electrostatic chuck 16 and attracted by the chuck mechanism. In addition, the inside of the processing chamber 11 is evacuated by the vacuum pump 14p connected to the gas exhaust port 14. When the inside of the processing chamber 11 reaches a predetermined pressure, the processing gas is supplied from the gas supply apparatus, which is not illustrated, to the gas supply chamber 62, and is supplied to the plasma processing chamber 61 via the gas blowing ports 18g of the shower head 18.

In addition, under the control of the control unit 50, a high frequency voltage is applied to the electrostatic chuck 16, which is a lower electrode, in a state where the shower head 18, which is an upper electrode, is grounded, and plasma is generated in the plasma processing chamber 61. On the lower electrode side, a potential gradient is generated between the plasma and the wafer 100 due to self-bias by the high frequency voltage, ions in the plasma are accelerated to the electrostatic chuck 16, and anisotropic etching processing is performed.

### Configuration Example of the Outer Circumferential Ring

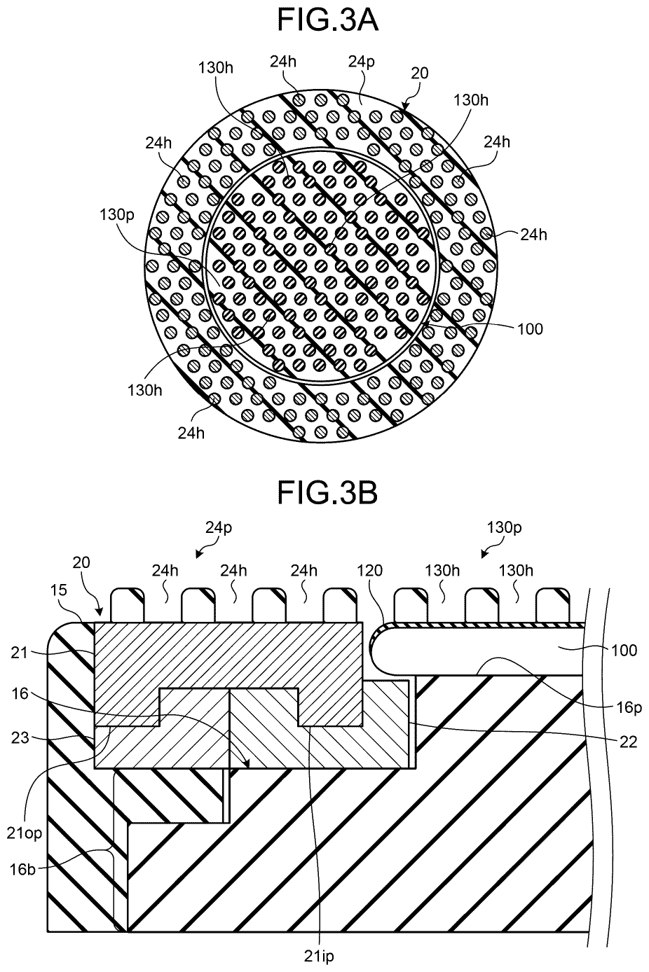

Next, a detailed configuration example of the outer circumferential ring 20 of the embodiment will be described with reference to FIGS. 3A and 3B. FIGS. 3A and 3B are diagrams illustrating an example of a detailed configuration of the outer circumferential ring 20 according to the embodiment. FIG. 3A is a top view of the outer circumferential ring 20 on an inner side of which the wafer 100 is arranged. FIG. 3B is a partially enlarged cross-sectional view of the outer circumferential ring 20 on an inner side of which the wafer 100 is arranged.

As illustrated in FIGS. 3A and 3B, the wafer 100 to be subjected to the plasma processing has, for example, a silicon oxide film 120 on the upper surface. The silicon oxide film 120 is, for example, an etching target film in the plasma processing apparatus 1.

On the silicon oxide film 120, for example, a mask pattern 130p having a plurality of holes 130h is formed. The plurality of holes 130h penetrates, for example, the mask pattern 130p, and the silicon oxide film 120 is exposed on the bottom surfaces of the plurality of holes 130h. In the etching processing by the plasma processing apparatus 1, the portion of the silicon oxide film 120 exposed from the mask pattern 130p is etched.

The mask pattern 130p is, for example, an organic film containing carbon such as a resist film. More specifically, the mask pattern 130p is, for example, a photocurable resist film or the like cured by ultraviolet light or the like.

The electrostatic chuck 16 includes a placement surface 16p on which the wafer 100 is placed and a rim portion 16b surrounding the placement surface 16p. The rim portion 16b has two steps descending toward the outside of the electrostatic chuck 16 away from the placement surface 16p.

A part of the lower surface of the outer circumferential ring 20 abuts on the step of the rim portion 16b on the inner side adjacent to the placement surface 16p. A lower surface of a part of the insulator ring 15 protruding to jut out to the placement surface 16p side of the electrostatic chuck 16 abuts on the step of the rim portion 16b on the outer side distant from the placement surface 16p.

The outer circumferential ring 20 includes an upper ring 21 and lower rings 22 and 23. The upper ring 21 and the lower rings 22 and 23 include, for example, silicon, silicon carbide, or the like as a main component. As described above, the outer circumferential ring 20 is made of a member having sufficient etching selectivity with respect to the silicon oxide film 120 to be etched.

The lower ring 22 is arranged so as to surround the placement surface 16p of the electrostatic chuck 16 on an inner side position of the outer circumferential ring 20, and is placed on the first step of the electrostatic chuck 16. The lower ring 23 is arranged so as to surround the lower ring 22 on an outer side position of the outer circumferential ring 20, and is placed on the insulator ring 15 protruding onto the second step of the electrostatic chuck 16.

The upper ring 21 is arranged on the lower rings 22 and 23. The upper surface height of the upper ring 21 on the lower rings 22 and 23 is substantially equal to the upper surface height of the wafer 100 placed on the placement surface 16p of the electrostatic chuck 16 at an initial value. By taking such a positional relationship, the plasma density is adjusted by the upper ring 21 so as to be substantially equal immediately above and outside the wafer 100.

In addition, the upper ring 21 has protruding portions 21ip and 21op protruding from the lower surface on an inner edge portion lower surface and an outer edge portion lower surface, respectively, and the protruding portion 21ip on the inner edge portion lower surface is fitted into a recess on the upper surface of the lower ring 22, and the protruding portion 21op on the outer edge portion lower surface is fitted into a recess on the upper surface of the lower ring 23.

On the upper surface of the upper ring 21, for example, a pattern 24p having a plurality of holes 24h is formed. The plurality of holes 24h penetrates, for example, the pattern 24p, and the upper surface of the upper ring 21 is exposed on the bottom surfaces of the plurality of holes 24h.

As described above, the pattern 24p on the upper surface of the upper ring 21 has a pattern substantially equal to the mask pattern 130p on the wafer 100, and the coverage of the pattern 24p with respect to the upper surface of the upper ring 21 is equal to the coverage of the mask pattern 130p with respect to the silicon oxide film 120 on the wafer 100 within a range of −20% or more and +20% or less. In addition, the pattern 24p preferably has, for example, a film thickness substantially equal to that of the mask pattern 130p on the wafer 100.

In addition, the pattern 24p on the upper surface of the upper ring 21 is, for example, an organic film containing carbon similarly to the mask pattern 130p on the wafer 100. More specifically, the pattern 24p is, for example, a photocurable resist film or the like cured by ultraviolet light or the like, and is preferably the same film type as the mask pattern 130p on the wafer 100.

### Semiconductor Device Manufacturing Method

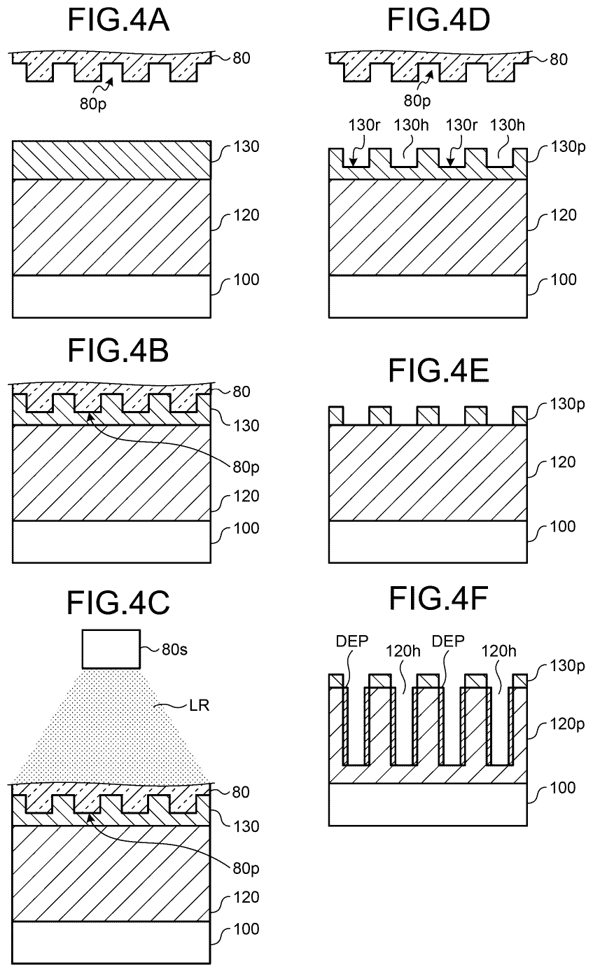

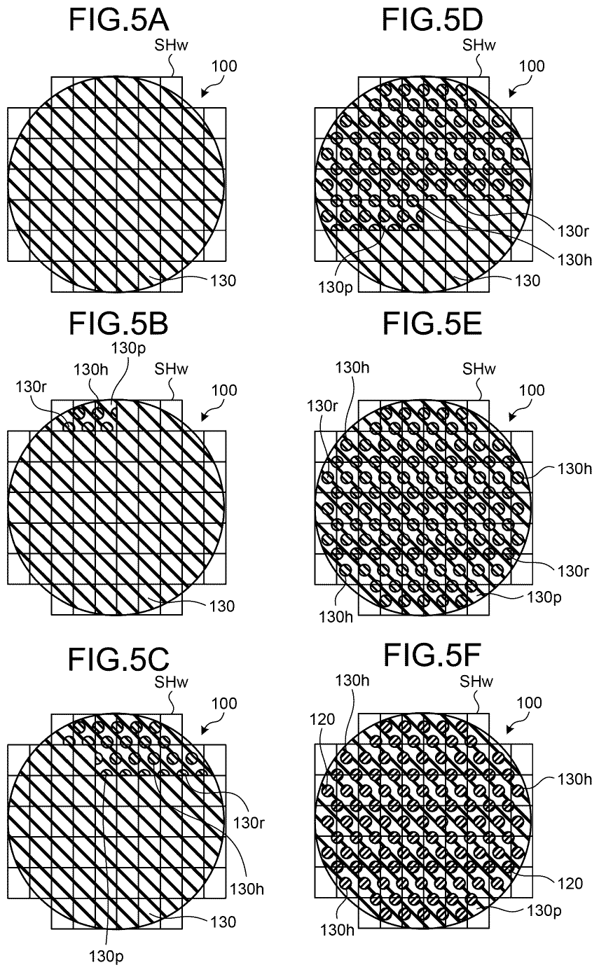

Next, an example of a semiconductor device manufacturing method according to the embodiment will be described with reference to FIGS. 4A to 5F. The semiconductor device manufacturing method according to the embodiment includes, for example, patterning processing of a mask film 130 using an imprint technique, etching processing by the plasma processing apparatus 1, and the like.

FIGS. 4A to 4F are cross-sectional views illustrating an example of a procedure of imprint processing and plasma processing on the wafer 100 according to the embodiment.

FIGS. 4A to 4D illustrate a state in which an imprint apparatus performs the imprint processing on the wafer 100.

As illustrated in FIG. 4A, the wafer 100 having the mask film 130 formed on the silicon oxide film 120 is loaded into the imprint apparatus, and a pattern surface 80p of a template 80 and the mask film 130 on the wafer 100 are caused to face each other.

The mask film 130 is, for example, a photocurable resist film or the like before the plurality of holes 130h is formed. The template 80 is an original plate for pattern transfer made of a transparent member such as quartz.

As illustrated in FIG. 4B, the relative positions of the template 80 and the wafer 100 are brought close to each other, and the pattern surface 80p of the template 80 is pressed against the mask film 130 on the wafer 100. At this time, a slight gap is maintained between the pattern surface 80p of the template 80 and the silicon oxide film 120 on the wafer 100 so that the template 80 and the wafer 100 do not come into contact with each other.

As illustrated in FIG. 4C, in a state where the pattern surface 80p is pressed against the mask film 130, light LR such as ultraviolet light is emitted from above the template 80 by a light source 80s of the imprint apparatus. The light LR from the light source 80s passes through the template 80, which is a transparent member, and is emitted to the mask film 130 to cure the mask film 130.

As illustrated in FIG. 4D, the template 80 is released from the mask film 130. Thus, for example, the mask pattern 130p having the plurality of holes 130h is formed. Since the template 80 is pressed so as to form a gap between the template 80 and the wafer 100, mask remaining films 130r having a slight thickness are formed on the bottom surfaces of the plurality of holes 130h.

As illustrated in FIG. 4E, the thickness of the entire mask pattern 130p is reduced by, for example, etching using oxygen plasma or the like, and the mask remaining films 130r are removed from the bottom surfaces of the holes 130h. The processing of removing the mask remaining films 130r may be performed in the plasma processing apparatus 1 described above before the etching processing of the silicon oxide film 120 is performed.

As illustrated in FIG. 4F, the plasma processing is performed on the wafer 100 in the plasma processing apparatus 1. At this time, the wafer 100 is arranged on an inner side with respect to the outer circumferential ring 20 having the aforementioned pattern 24p on the outermost surface.

In the etching processing in the plasma processing apparatus 1, for example, a corrosive processing gas is supplied into the processing chamber 11 to generate plasma. Thus, the silicon oxide film 120 exposed from the mask pattern 130p is etched, and a plurality of holes 120h is formed in the silicon oxide film 120.

At this time, although the processing condition that the mask pattern 130p has high etching selectivity with respect to the silicon oxide film 120 is used, the mask pattern 130p is also slightly etched. An etching product generated by the etching of the mask pattern 130p becomes organic deposition films DEP containing carbon and is deposited on the sidewalls of the plurality of holes 120h formed in the silicon oxide film 120. Thus, the sidewalls of the plurality of holes 120h are protected, and occurrence of side etching or the like on the sidewalls is suppressed.

Here, in the vicinity of the outer edge portion of the wafer 100, the coverage of the mask pattern 130p per unit area of the silicon oxide film 120 is smaller than, for example, that in the vicinity of the central portion of the wafer 100. However, on an outer side of the outer edge portion of the wafer 100, for example, the pattern 24p made of the same type of film of the mask pattern 130p and including the component of the deposition film DEP generated by the plasma reaction is formed on the outermost surface of the outer circumferential ring 20.

Therefore, a depositing etching product is supplied from not only the mask pattern 130p, but also the pattern 24p on the outer circumferential ring 20 to the outer edge portion of the wafer 100 and becomes the deposition films DEP to protect the side surfaces of the plurality of holes 120h. Thus, also at the outer edge portion of the wafer 100, occurrence of side etching or the like on the sidewalls of the plurality of holes 120h is suppressed.

By the above etching processing, a silicon oxide pattern 120p having the plurality of holes 120h is formed. The wafer 100 having subjected to the etching processing is discharged from the plasma processing apparatus 1.

Then, the mask pattern 130p on the silicon oxide pattern 120p is removed, for example, by ashing using oxygen plasma or the like. At this time, the deposition films DEP on the sidewalls of the plurality of holes 120h are also removed.

Thereafter, the semiconductor device of the embodiment is manufactured on the wafer 100 through a plurality of further processes.

Here, details of the imprint processing on the wafer 100 are illustrated in FIGS. 5A to 5F. FIGS. 5A to 5F are top views illustrating an example of a detailed procedure of the imprint processing on the wafer 100 according to the embodiment.

As illustrated in FIG. 5A, the mask film 130 is formed on the wafer 100 by a spin coating method or the like, and the entire wafer 100 is divided into a plurality of shot regions SHw. However, the mask film 130 may be formed by, for example, an inkjet method or the like. When the mask film 130 is formed by the inkjet method, the mask film 130 may be sequentially formed for each shot region SHw for each impress processing of the template 80 performed for each shot region SHw as described below.

As illustrated in FIG. 5B, in the imprint processing, the template 80 is pressed against the mask film 130 for each of the plurality of shot regions SHw to form the mask pattern 130p. In the examples of FIGS. 5A to 5F, for example, the imprint processing proceeds from the shot region SHw at the outermost periphery at the upper left on the sheet of paper toward the left side on the sheet of paper. At this stage, the mask remaining films 130r are still formed on the bottom surfaces of the plurality of holes 130h of the already formed mask pattern 130p.

Note that, although some holes 130h are in a state of missing at the boundary of the shot regions SHw, this is for convenience of drawing, and does not mean that the holes 130h are in a state of missing during the formation in the actual imprint processing.

As illustrated in FIG. 5C, for example, when the imprint processing is performed on the shot region SHw in the uppermost row on the sheet of paper, the imprint processing proceeds, for example, from right to left on the shot region SHw in the second row from the uppermost row on the sheet of paper.

As illustrated in FIG. 5D, the imprint processing proceeds while the traveling direction is reversed horizontally for each row. Such a processing order may be referred to as, for example, a raster method or the like.

As illustrated in FIG. 5E, the imprint processing for all the shot regions SHw ends.

As illustrated in FIG. 5F, the mask remaining film 130r of the mask pattern 130p formed in each of the plurality of shot regions SHw is removed by, for example, etching using oxygen plasma or the like. Thus, the silicon oxide film 120 on the wafer 100 is exposed from the bottom surfaces of the plurality of holes 130h.

### Method for Manufacturing the Outer Circumferential Ring

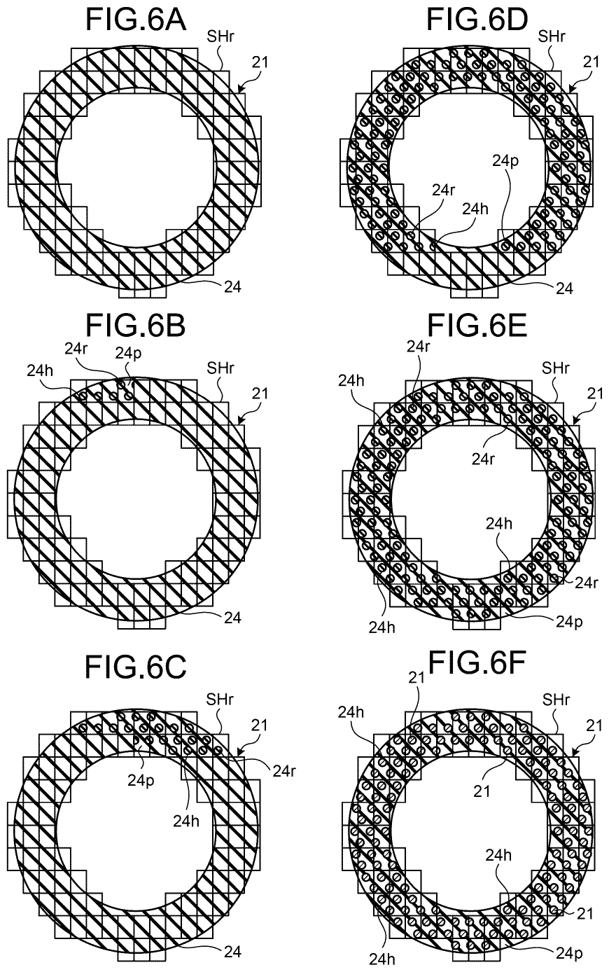

Next, an example of a method for manufacturing the outer circumferential ring 20 according to the embodiment will be described with reference to FIGS. 6A to 6F. FIGS. 6A to 6F are top views illustrating an example of a procedure of processing of forming the pattern 24p on the upper surface of the upper ring 21 according to the embodiment. Note that the method for manufacturing the outer circumferential ring 20 may also be included in the semiconductor device manufacturing method of the embodiment.

In manufacturing the outer circumferential ring 20, for example, a silicon-based member containing silicon or silicon carbide as a main component is cut out to form each of the upper ring 21 and the lower rings 22 and 23.

In addition, as described below, the pattern 24p is formed on the upper surface of the formed upper ring 21 using, for example, an imprint technique.

As illustrated in FIG. 6A, a carbon-based film 24 such as a photocurable resist film is formed on the upper surface of the upper ring 21 by, for example, an inkjet method or the like, similarly to the mask pattern 130p of the wafer 100, and the entire upper ring is divided into a plurality of shot regions SHr. Note that the carbon-based film 24 may be sequentially formed in each of the shot regions SHw for each impress processing on the template 80.

In addition, the carbon-based film 24 preferably has a film thickness substantially equal to that of the mask film 130 before the imprint processing in FIG. 4A and the like described above. Thus, the pattern 24p after the imprint processing can have, for example, a film thickness substantially equal to that of the mask pattern 130p on the wafer 100.

As illustrated in FIG. 6B, in the imprint processing with respect to the upper ring 21, a template is pressed against the carbon-based film 24 for each of the plurality of shot regions SHr to form the pattern 24p. At this time, it is preferable to use the same type of template having the same pattern as the template 80 used when the imprint processing is performed on the wafer 100.

In addition, also in the examples of FIGS. 6A to 6F, for example, the imprint processing proceeds from the shot region SHr at the outermost periphery at the upper left on the sheet of paper toward the left side on the sheet of paper. At this stage, carbon-based remaining films 24r are still formed on the bottom surfaces of the plurality of holes 24h of the already formed pattern 24p.

Note that, although some holes 24h are in a state of missing at the boundary of the shot regions SHr, this is for convenience of drawing, and does not mean that the holes 24h are in a state of missing during the formation in the actual imprint processing.

As illustrated in FIG. 6C, when the imprint processing is performed on the shot region SHr in the uppermost row on the sheet of paper, the imprint processing proceeds from right to left on the shot region SHr in the second row from the uppermost row on the sheet of paper according to the processing order of the raster method, for example, as in the example of FIGS. 5A to 5F.

As illustrated in FIG. 6D, the imprint processing further proceeds while the traveling direction is reversed horizontally for each row.

As illustrated in FIG. 6E, the imprint processing for all the shot regions SHr ends.

As illustrated in FIG. 6F, the carbon-based remaining film 24r of the pattern 24p formed in each of the plurality of shot regions SHr is removed by, for example, etching using oxygen plasma or the like. Thus, the upper surface of the upper ring 21 is exposed from the bottom surfaces of the plurality of holes 24h.

As described above, the outer circumferential ring 20 of the embodiment is manufactured.

Note that, in a case where the processing of removing the mask remaining films 130r of the wafer 100 illustrated in FIG. 5F described above is performed in the plasma processing apparatus 1 or the like, the processing in FIG. 6F may also be performed in the plasma processing apparatus 1 in parallel with the processing on the wafer 100.

In this case, the upper ring 21 is loaded into the processing chamber 11 of the plasma processing apparatus 1 in the state of FIG. 6E.

### Use Example of the Outer Circumferential Ring

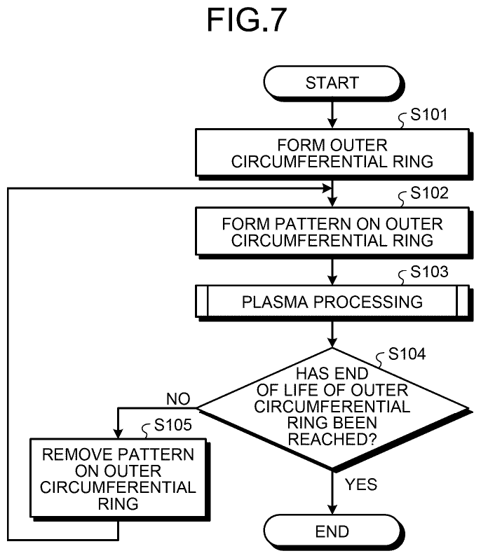

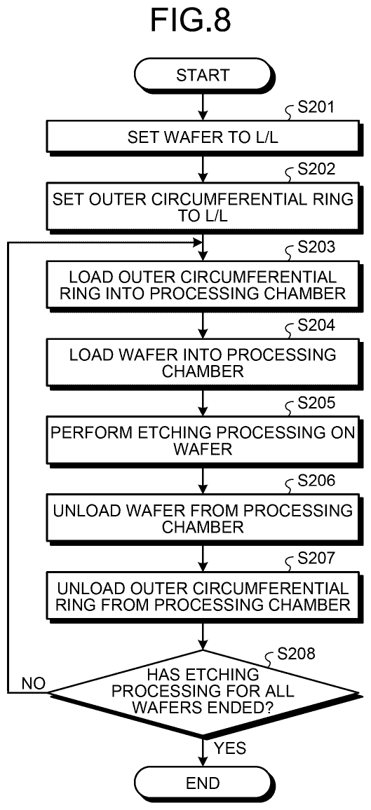

Next, a manufacturing flow of the semiconductor device using the outer circumferential ring 20 of the embodiment will be described with reference to FIGS. 7 and 8. FIG. 7 is a flowchart illustrating an example of a use cycle of the outer circumferential ring 20 according to the embodiment.

As illustrated in FIG. 7, the silicon-based member such as silicon or silicon carbide is formed to form the upper ring 21 and the lower rings 22 and 23 (Step S101). In addition, the carbon-based film 24 is formed on the formed upper ring 21, and the imprint processing is performed to form the pattern 24p (Step S102). Thus, the outer circumferential ring 20 is manufactured.

The outer circumferential ring 20 having the pattern 24p formed on the outermost surface is used for plasma processing in the plasma processing apparatus 1 (Step S103).

As described above, as the member of the outer circumferential ring 20, for example, a material having high etching selectivity is selected in etching of the silicon oxide film 120. However, the pattern 24p on the outer circumferential ring 20 is etched by the plasma processing, and the upper surface of the outer circumferential ring 20 exposed from the pattern 24p is also slightly etched.

Therefore, after the plasma processing, it is determined whether or not the outer circumferential ring 20 has reached the end of the life (Step S104). The life determination can be performed on the basis of whether or not the integration time in which the outer circumferential ring 20 is used for the plasma processing exceeds a predetermined time. The etching amount of the outer circumferential ring 20 may be measured, and the life determination may be performed on the basis of whether or not the etching amount exceeds a predetermined value.

Note that the upper ring 21 and the lower rings 22 and 23 constituting the outer circumferential ring 20 may have different lives. For example, the upper ring 21 located on the outermost surface of the outer circumferential ring 20 tends to be more exposed to plasma and have a shorter life than the lower rings 22 and 23. Therefore, it is preferable that different lives are set for each of the upper ring 21 and the lower rings 22 and 23, and the life determination is performed for each ring.

When the outer circumferential ring 20 has not reached the end of the life (Step S104: No), the pattern 24p remaining on the upper surface of the outer circumferential ring 20 is removed by ashing using, for example, oxidation plasma or the like (Step S105). In addition, although the used pattern 24p is removed, a pattern 24p is newly formed on the outer circumferential ring 20 (Step S102) and is used for the plasma processing until the end of life is reached.

When the outer circumferential ring 20 has reached the end of the life (Step S104: Yes), the use of the outer circumferential ring 20 is terminated.

Thus, the use cycle of the outer circumferential ring 20 of the embodiment ends.

The outer circumferential ring 20 that has reached the end of the life is discarded, or is melted so that the material is used for forming a new outer circumferential ring 20.

FIG. 8 is a flowchart illustrating an example of a procedure of plasma processing using the outer circumferential ring 20 according to the embodiment. The flow of FIG. 8 is details of the processing of Step S103 of FIG. 7 described above.

As illustrated in FIG. 8, a plurality of wafers 100, for example, wafers 100 for one lot are set in the load lock 81 of the plasma processing apparatus 1 (Step S201). Under the control of the control unit 50, the atmosphere of the load lock 81 is exhausted by a pump or the like, which is not illustrated, and the pressure of the load lock 81 is reduced so that the wafer 100 is brought into a state of being capable of being transferred in vacuum.

In addition, a plurality of outer circumferential rings 20, for example, the same number of outer circumferential rings 20 as the wafers 100 set in the load lock 81 are set in the load lock 91 (Step S202). The pattern 24p has already been formed on the upper surfaces of these outer circumferential rings 20.

In addition, under the control of the control unit 50, the atmosphere of the load lock 91 is exhausted by a pump or the like, which is not illustrated, and the pressure of the load lock 91 is reduced so that the outer circumferential ring 20 is brought into a state of being capable of being transferred in vacuum.

Under the control of the control unit 50, a set of lower rings 22 and 23 and upper ring 21 constituting the outer circumferential ring 20 is sequentially loaded into the processing chamber 11 under reduced pressure (Step S203). In addition, one wafer 100 is loaded into the processing chamber 11 under reduced pressure (Step S204).

The wafer 100 is placed on the placement surface 16p of the electrostatic chuck 16 and electrostatically attracted to the placement surface 16p. Thus, the outer circumferential ring 20 on which the pattern 24p is formed is in a state of being arranged on an outer circumferential portion of the wafer 100.

The processing gas is supplied through the gas Supply port 13 into the processing chamber 11 by the control unit 50, and the high frequency power is supplied from the high frequency power supply 44 to the electrostatic chuck 16. Thus, plasma is generated in the processing chamber 11, and the wafer 100 is subjected to the etching processing (Step S205).

By the above etching processing, for example, the plurality of holes 120h is formed in the silicon oxide film 120 on the wafer 100. At this time, the etching product is supplied from the mask pattern 130p on the wafer 100 and the pattern 24p on the outer circumferential ring 20, and the deposition films are formed on the sidewalls of the plurality of holes 120h to protect the sidewalls of the holes 120h.

When the etching processing on the wafer 100 ends, the control unit 50 stops the supply of power from the high frequency power supply 44, stops the supply of the processing gas into the processing chamber 11, and the plasma disappears.

Under the control of the control unit 50, the processed wafer 100 is unloaded from the processing chamber 11 under reduced pressure and collected into the load lock 82 (Step S206). In addition, under the control of the control unit 50, the used outer circumferential ring 20 is unloaded from the processing chamber 11 under reduced pressure and collected into the load lock 92 (Step S207).

At this time, the lower rings 22 and 23 before reaching the end of the life may not be collected. It is preferable to reform the pattern 24p every time the upper ring 21 is used for the etching processing on one wafer 100. Therefore, the upper ring 21 is collected for each etching processing regardless of whether or not the upper ring has reached the end of the life.

After unloading the wafer 100, the upper ring 21, and the like, the control unit 50 determines whether or not the etching processing has ended for all the wafers 100 set in the load lock 81 (Step S208). When the etching processing for all the wafers 100 has ended (Step S208: Yes), the etching processing for the lot ends.

In a case where there is an unprocessed wafer 100 (Step S208: No), the processing of Step S203 and the subsequent steps is repeated by the control unit 50.

Thus, the plasma processing using the outer circumferential ring 20 of the embodiment ends.

When the plasma processing for all the wafers 100 ends, for example, the outer circumferential rings 20 for one lot are sent to the processing of Step S104 and the subsequent steps of FIG. 7.

### Overview

In the process of manufacturing the semiconductor device, for example, the etching processing may be performed on the wafer. In the etching processing, for example, a part of the etching target film is covered with a mask pattern, and a portion exposed from the mask pattern is etched. At this time, a part of the mask pattern is etched, and the etching product is deposited on the sidewall or the like of the etching target film, and occurrence of side etching or the like on the sidewall of the etching target film is suppressed.

However, since the coverage of the mask pattern with respect to the etching target film is lower in the outer edge portion of the wafer than in the vicinity of the central portion of the wafer, a sufficient deposition film does not adhere to the sidewall, and side etching or the like can occur in the etching target film. Thus, a desired processed shape cannot be obtained at the outer edge portion of the wafer, or variations can occur in the processed shape between the central portion and the outer edge portion of the wafer.

With the plasma processing apparatus 1 of the embodiment, the outer circumferential ring 20 has the pattern 24p including the component of the deposition film generated by the plasma reaction on the outermost surface. Thus, at the outer edge portion of the wafer 100, the etching product is also supplied from the pattern 24p on the outer circumferential ring 20.

Therefore, for example, a sufficient amount of deposition film can be adhered to the sidewalls of the holes 120h of the silicon oxide film 120, which is an etching target film, to suppress side etching or the like, and variations in processing characteristics between the central portion and the outer edge portion of the wafer 100 can be suppressed.

The plasma processing apparatus 1 according to the embodiment includes the load lock 91 that stores the outer circumferential ring 20, and the transfer arm 72 that transfers the outer circumferential ring between the load lock 91 and the processing chamber 11.

Thus, the unused outer circumferential ring 20 can be loaded into the processing chamber 11, for example, for each etching processing while the entire plasma processing apparatus 1 is maintained under reduced pressure. Therefore, the time required for installing the outer circumferential ring 20 can be shortened to improve the throughput of the plasma processing apparatus 1, and the condition of the etching processing for each wafer 100 can be kept constant.

With the plasma processing apparatus 1 of the embodiment, the transfer arm 72 transfers the outer circumferential ring 20 between the load lock 92 that collects the outer circumferential ring 20 used for processing the wafer 100 and the processing chamber 11.

Thus, the outer circumferential ring 20 can be replaced, for example, for each etching processing while the entire plasma processing apparatus 1 is maintained under reduced pressure. Therefore, the time required for replacing the outer circumferential ring 20 can be shortened to improve the throughput of the plasma processing apparatus 1.

By the semiconductor device manufacturing method of the embodiment, the coverage of the pattern 24p of the outer circumferential ring 20 with respect to the outermost surface of the outer circumferential ring 20 is −20% or more and +20% or less of the coverage of the mask pattern 130p of the wafer 100 with respect to the surface of the wafer 100.

Thus, it is possible to further bring the supply amounts of the etching product, which is a component of the deposition film, closer to each other between the central portion and the outer edge portion of the wafer 100. Therefore, it is possible to further suppress variations in processing characteristics between the central portion and the outer edge portion of the wafer 100.

By the semiconductor device manufacturing method of the embodiment, the mask pattern 130p and the pattern 24p contain, for example, carbon, and more specifically, contain a resist as a main component.

As described above, since the mask pattern 130p and the pattern 24p contain the same type of component and furthermore are made of the same type of film, the conditions of the etching processing can be further brought closer to each other between the central portion and the outer edge portion of the wafer 100. Thus, it is possible to further suppress variations in processing characteristics between the central portion and the outer edge portion of the wafer 100.

By the semiconductor device manufacturing method of the embodiment, when the pattern 24p is formed on the outermost surface of the outer circumferential ring 20, the same type of template as the template 80 used for forming the mask pattern 130p of the wafer 100 is used. Thus, the pattern 24p substantially equal to the mask pattern 130p of the wafer 100 can be formed on the outermost surface of the outer circumferential ring 20.

Therefore, it is possible to further bring the conditions of the etching processing closer to each other between the central portion and the outer edge portion of the wafer 100, and it is possible to further suppress variations in processing characteristics between the central portion and the outer edge portion of the wafer 100.

By the semiconductor device manufacturing method of the embodiment, after the wafer 100 is processed, the outer circumferential ring 20 is unloaded from the processing chamber 11, the used pattern 24p is removed, and the pattern 24p is formed on the outermost surface. Thus, the outer circumferential ring 20 can be repeatedly used until the end of the life is reached, and the manufacturing cost of the semiconductor device can be reduced.

### First and Second Modifications

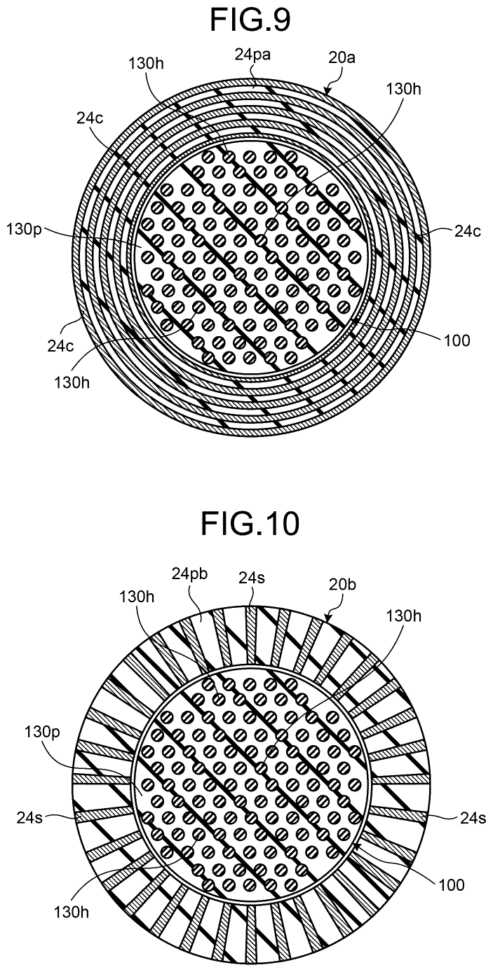

Next, a configuration example of outer circumferential rings 20a and 20b of the first and second modifications of the embodiment will be described with reference to FIGS. 9 and 10. In the outer circumferential rings 20a and 20b of the first and second modifications, patterns 24pa and 24pb formed on the upper surface are different from that of the above-described embodiment.

FIGS. 9 and 10 are top views illustrating an example of a configuration of the outer circumferential rings 20a and 20b according to the first and second modifications of the embodiment. Note that, in FIGS. 9 and 10, the same reference numerals as those of the above-described embodiment are assigned to the same configurations as those of the above-described embodiment such as the wafer 100, and the description thereof will be omitted.

In addition, in the outer circumferential rings 20a and 20b of FIGS. 9 and 10, the patterns 24pa and 24pb after removal of the carbon-based remaining films 24r are illustrated. In addition, in the wafer 100 of FIGS. 9 and 10, the mask pattern 130p after removal of the mask remaining films 130r is illustrated.

As illustrated in FIGS. 9 and 10, the outer circumferential rings 20a and 20b may not have the same pattern as, for example, the mask pattern 130p on the wafer 100.

In the example illustrated in FIG. 9, the outer circumferential ring 20a of the first modification has, for example, the pattern 24pa in which annular grooves 24c are concentrically formed on the outermost surface. The upper surface of the outer circumferential ring 20a is exposed from the bottom surfaces of the grooves 24c.

Also in the outer circumferential ring 20a of the first modification, the coverage of the pattern 24pa with respect to the upper surface of the outer circumferential ring 20a is equal within a range of −20% or more and +20% or less as compared with the coverage of the mask pattern 130p with respect to the silicon oxide film 120 on the wafer 100.

In addition, also in the outer circumferential ring 20a of the first modification, the pattern 24pa on the upper surface of the outer circumferential ring 20a is, for example, an organic film containing carbon similarly to the mask pattern 130p on the wafer 100. More specifically, the pattern 24pa is a photocurable resist film or the like cured by ultraviolet light or the like, and is preferably the same film type as the mask pattern 130p on the wafer 100.

In the example illustrated in FIG. 10, the outer circumferential ring 20b of the second modification has, for example, the pattern 24pb in which grooves 24s radially expanding toward the outside of the outer circumferential ring 20b are formed on the outermost surface. The upper surface of the outer circumferential ring 20b is exposed from the bottom surfaces of the grooves 24s.

Also in the outer circumferential ring 20b of the second modification, the coverage of the pattern 24pb with respect to the upper surface of the outer circumferential ring 20b is equal within a range of −20% or more and +20% or less as compared with the coverage of the mask pattern 130p with respect to the silicon oxide film 120 on the wafer 100.

In addition, also in the outer circumferential ring 20b of the second modification, the pattern 24pb on the upper surface of the outer circumferential ring 20b is, for example, an organic film containing carbon similarly to the mask pattern 130p on the wafer 100. More specifically, the pattern 24pb is a photocurable resist film or the like cured by ultraviolet light or the like, and is preferably the same film type as the mask pattern 130p on the wafer 100.

The plasma processing apparatus including the outer circumferential rings 20a and 20b of the first and second modifications provides the same effect as that of the plasma processing apparatus 1 of the above-described embodiment.

### Other Modifications

When the wafer is subjected to the etching processing, not only the hole pattern described above, but also a line-and-space pattern in which lines and spaces are alternately arranged, a dot pattern in which a plurality of protrusions is arranged, and other various mask patterns can be used. Therefore, for example, the line-and-space pattern, the dot pattern, or another pattern may be formed on the upper surface of the outer circumferential ring in accordance with the mask pattern formed on the wafer.

In addition, the mask pattern on the wafer and the pattern on the upper surface of the outer circumferential ring may be formed using a photolithography technique instead of the imprint technique. In this case, the mask pattern on the wafer and the pattern on the upper surface of the outer circumferential ring can be formed by irradiating the resist film or the like with exposure light through a reticle having a predetermined pattern. In addition, also in this case, the same type of reticle as the reticle used for forming the mask pattern may be used when forming the pattern on the upper surface of the outer circumferential ring.

In addition, the mask pattern formed on the wafer can be formed of not only the above-described resist film, but also a film containing carbon such as a spin on carbon (SOC) film or a chemical vapor deposition (CVD) carbon film.

Even in this case, the pattern on the upper surface of the outer circumferential ring can be formed of a film containing carbon such as the resist film described above. Since the resist film, the SOC film, and the CVD carbon film have close compositions and similar etching characteristics, even in this case, the same effects as those of the above-described embodiment and first and second modifications can be obtained.

However, for example, in accordance with the film type of the mask pattern on the wafer, the pattern of the outer circumferential ring may also be made of the SOC film, the CVD carbon film, or the like. Thus, it is possible to further bring the conditions of the etching processing closer to each other between the central portion and the outer edge portion of the wafer, and it is possible to further suppress variations in processing characteristics between the central portion and the outer edge portion of the wafer.

Note that when the mask pattern on the wafer and the pattern on the upper surface of the outer circumferential ring are formed of the SOC film, the CVD carbon film, or the like, a resist pattern or the like may be formed on the SOC film or the CVD carbon film by a photolithography technique, an imprint technique, or the like, and the SOC film or the CVD carbon film may be etched using the resist pattern or the like as a mask.

In addition, the film to be subjected to the etching processing may be not only the silicon oxide film described above, but also a polysilicon film, a single crystal silicon film, or the like. The single crystal silicon film can be formed on the wafer using, for example, an epitaxial growth method or the like, and there is a case where the single crystal silicon film constituting a part of the wafer becomes an etching target as it is.

In such a case, the outer circumferential ring can be made of a silicon-based material such as silicon oxide or silicon carbide. Thus, the outer circumferential ring having high etching selectivity with respect to the polysilicon film, the single crystal silicon film, or the like to be etched is obtained.

In addition, when the polysilicon film, the single crystal silicon film, or the like is to be etched, a mask pattern may be formed of a film containing silicon such as a silicon oxide film instead of the mask pattern formed of a film containing carbon such as a resist film, an SOC film, or a CVD carbon film. In this case, the deposition film containing silicon is formed of the mask pattern so as to be a sidewall protective film.

Therefore, for example, in accordance with the mask pattern on the wafer, the pattern on the outer circumferential ring can also be formed of a film containing silicon such as a silicon oxide film. Thus, the etching product, which is a component of the deposition film, can be supplied to the outer edge portion of the wafer from the pattern on the outer circumferential ring.

When the pattern on the outer circumferential ring is formed of a silicon oxide film or the like, for example, the used pattern on the outer circumferential ring can be removed by etching under a condition having high selectivity with respect to the constituent members of the outer circumferential ring. Alternatively, the pattern on the outer circumferential ring may be removed by polishing by chemical mechanical polishing (CMP) or the like.

In addition, for example, when a pattern different from the mask pattern on the wafer is formed on the outer circumferential ring as in the first and second modifications, a reticle or a template different from a reticle or a template used for forming the mask pattern is used.

Since the coverage of the mask pattern on the wafer can vary, in the above case, a plurality of types of reticles or templates having different coverages may be prepared for formation of a pattern on the outer circumferential ring such that the coverage of the pattern on the outer circumferential ring is within ±20% of the coverage of the mask pattern.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device manufacturing method, the method comprising:
loading a substrate into a processing container including an upper electrode;
placing the substrate on a substrate placement table including a lower electrode facing the upper electrode in the processing container;
supplying power to at least one of the upper electrode and the lower electrode to generate plasma in the processing container to process the substrate; and
when processing the substrate,
arranging an outer circumferential ring having a pattern including a component of a deposition film generated by a plasma reaction on an outermost surface on an outer edge portion of the substrate placement table.

2. The semiconductor device manufacturing method according to claim 1, wherein
the substrate has a mask pattern, and
a coverage of the pattern with respect to the outermost surface of the outer circumferential ring is −20% or more and +20% or less of a coverage of the mask pattern with respect to a surface of the substrate.

3. The semiconductor device manufacturing method according to claim 2, wherein
the mask pattern and the pattern contain carbon.

4. The semiconductor device manufacturing method according to claim 2, wherein
the mask pattern and the pattern both contain a resist, SOC, or CVD carbon as a main component.

5. The semiconductor device manufacturing method according to claim 2, wherein
when the substrate is processed,
a silicon oxide film formed on the substrate is etched.

6. The semiconductor device manufacturing method according to claim 2, wherein
the mask pattern and the pattern contain silicon.

7. The semiconductor device manufacturing method according to claim 2, wherein
the mask pattern and the pattern contain silicon oxide as a main component.

8. The semiconductor device manufacturing method according to claim 2, wherein
when the substrate is processed,
a polysilicon film formed on the substrate or a single crystal silicon film formed on the substrate or constituting a part of the substrate is etched.

9. The semiconductor device manufacturing method according to claim 2, wherein
before the substrate is processed,
a film containing the component is formed on the outermost surface of the outer circumferential ring,
the film is patterned using a lithography technique or an imprint technique to form the pattern on the outermost surface, and
the outer circumferential ring on which the pattern is formed is loaded into the processing container.

10. The semiconductor device manufacturing method according to claim 9, wherein
when the pattern is formed,
a reticle or a template of a same type as a reticle or a template used for forming the mask pattern is used.

11. The semiconductor device manufacturing method according to claim 9, wherein
after the substrate is processed,
the outer circumferential ring is unloaded from the processing container,
the pattern of the outer circumferential ring unloaded from the processing container is removed, and
the pattern is formed on the outermost surface of the outer circumferential ring from which the pattern has been removed.
